(19) United States
(12) Patent Application Publication
(10) Pub. No.: US 2024/0008368 A1
(43) Pub. Date: Jan. 4, 2024

(54) PIEZOELECTRIC ELEMENT UNIT AND RESONATOR

(71) Applicant: ROHM CO., LTD., Kyoto (JP)

(72) Inventor: Noriyuki SHIMOJI, Kyoto (JP)

(73) Assignee: ROHM CO., LTD., Kyoto (JP)

(21) Appl. No.: 18/345,821

(22) Filed: Jun. 30, 2023

(30) Foreign Application Priority Data
Jul. 4, 2022 (JP) 2022-107737

(51) Int. Cl. H10N 30/87; H10N 30/88; H10N 30/50; H10N 30/853; H03H 9/17

(52) U.S. Cl. CPC H10N 30/871; H10N 30/883; H10N 30/505; H10N 30/877; H10N 30/8542; H03H 9/171

(57) ABSTRACT

A piezoelectric element unit includes: a substrate having a main surface; a piezoelectric film arranged on the substrate and having a first side surface, a second side surface opposite the first side surface, and a bottom surface that faces the main surface and is connected to the first side surface and the second side surface; a first electrode arranged on the substrate and in contact with the first side surface of the piezoelectric film; and a second electrode arranged on the substrate in contact with at least one of the first side surface and the second side surface of the piezoelectric film, and provided to be separated from the first electrode.

### CROSS-REFERENCE TO RELATED APPLICATION

This application is based upon and claims the benefit of priority from Japanese Patent Application No. 2022-107737, filed on Jul. 4, 2022, the entire contents of which are incorporated herein by reference.

### TECHNICAL FIELD

The present disclosure relates to a piezoelectric element unit and a resonator.

### BACKGROUND

The use of mobile devices such as smartphones, for which there is a strong demand for miniaturization and power saving, is rapidly expanding. In wireless communication systems for portable devices, devices using radio frequencies in the GHz band are being actively developed. In radio-frequency circuits used in these wireless communication systems, IF (Intermediate Frequency) filters and RF (Radio Frequency) filters are used in analog circuit portions.

The filters described above are for passing only signals of a desired frequency band and blocking signals of other frequencies. For example, an RF filter is composed of a plurality of resonant elements and has a desired filter band formed by a ladder circuit in which the resonant elements are connected in a ladder shape.

A specific example of the filter may be a surface acoustic wave (SAW) filter using a SAW element. As an alternative to the SAW filter, there may be a BAW filter using a piezoelectric thin film resonant (bulk acoustic wave (BAW)) element, and the development of these filters is underway.

As mobile devices such as smartphones evolve, the number of signals having frequency bands that need to be processed within the devices increases. For example, smartphones for 5G use fifty filters or more.

### BRIEF DESCRIPTION OF DRAWINGS

The accompanying drawings, which are incorporated in and constitute a part of the specification, illustrate embodiments of the present disclosure.

FIG. 1A is a partial top view for explaining a piezoelectric element unit according to a first embodiment.

FIG. 1B is a partial cross-sectional view taken along line A-A in FIG. 1A.

FIG. 1C is a partial cross-sectional view taken along line B-B in FIG. 1A.

FIG. 2A is a partial top view for explaining a piezoelectric element unit according to a first modification of the first embodiment.

FIG. 2B is a partial cross-sectional view taken along line A-A in FIG. 2A.

FIG. 2C is a partial cross-sectional view taken along line B-B in FIG. 2A.

FIG. 3A is a partial top view for explaining a piezoelectric element unit according to a second modification of the first embodiment.

FIG. 3B is a partial cross-sectional view taken along line A-A in FIG. 3A.

FIG. 3C is a partial cross-sectional view taken along line B-B in FIG. 3A.

FIG. 4A is a partial top view for explaining a piezoelectric element unit according to a second embodiment.

FIG. 4B is a partial cross-sectional view taken along line A-A in FIG. 4A.

FIG. 4C is a partial cross-sectional view taken along line B-B in FIG. 4A.

FIG. 5A is a partial top view for explaining a piezoelectric element unit according to a first modification of the second embodiment.

FIG. 5B is a partial cross-sectional view taken along line A1-A1 in FIG. 5A.

FIG. 5C is a partial cross-sectional view taken along line A2-A2 in FIG. 5A.

FIG. 6 is a partial top view for explaining a piezoelectric element unit according to a second modification of the second embodiment.

FIG. 7A is a partial top view for explaining a piezoelectric element unit according to a third modification of the second embodiment.

FIG. 7B is a partial cross-sectional view taken along line A-A in FIG. 7A.

FIG. 7C is a partial cross-sectional view taken along line B-B in FIG. 7A.

FIG. 8A is a partial top view for explaining a resonator according to a third embodiment.

FIG. 8B is a partial cross-sectional view taken along line A-A in FIG. 8A.

FIG. 8C is a partial cross-sectional view taken along line B-B in FIG. 8A.

FIG. 9A is a partial top view for explaining a resonator according to a modification of the third embodiment.

FIG. 9B is a partial cross-sectional view taken along line A-A in FIG. 9A.

FIG. 9C is a partial cross-sectional view taken along line B-B in FIG. 9A.

FIG. 10A is a partial top view for explaining a piezoelectric element unit according to a fourth embodiment.

FIG. 10B is a partial cross-sectional view taken along line A-A in FIG. 10A.

FIG. 11A is a partial cross-sectional view (1) illustrating a space.

FIG. 11B is a partial cross-sectional view (2) illustrating a space.

FIG. 12 is a partial cross-sectional view for explaining a piezoelectric element unit including a sidewall insulating film.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Next, the present embodiment will be described with reference to the accompanying drawings. In the following description of the drawings, the same or similar parts will be denoted by the same or similar reference numerals. However, it should be noted that the drawings are schematic and the relationship between the thickness of each component and the planar dimensions, and the like, may differ from reality. Therefore, specific thicknesses and dimensions should be determined with reference to the following description. Also, there may be a case where the relationship of dimensions and the ratios differ from each other between the drawings.

Further, the following embodiments are examples of an apparatus and method for embodying technical ideas and do not specify the material, shape, structure, arrangement, and the like of each component. Various modifications may be made to the present embodiment within the scope of the claims.

A specific aspect of the present embodiment is as follows.

<1> A piezoelectric element unit includes: a substrate having a main surface; a piezoelectric film arranged on the substrate and having a first side surface, a second side surface opposite the first side surface, and a bottom surface that faces the main surface and is connected to the first side surface and the second side surface; a first electrode arranged on the substrate and in contact with the first side surface of the piezoelectric film; and a second electrode arranged on the substrate in contact with at least one of the first side surface and the second side surface of the piezoelectric film, and provided to be separated from the first electrode.

According to <1> above, in the piezoelectric element unit including the piezoelectric film, the first electrode, and the second electrode for efficiently propagating a surface acoustic wave or a bulk acoustic wave between the electrodes, it is possible to widen the first side surface and the second side surface of the piezoelectric film and to reduce an area occupied by the piezoelectric element on the main surface of the substrate. Therefore, the piezoelectric element can be miniaturized and packaged at a high density, and as a result, the piezoelectric element unit suitable for miniaturization and high packaging density can be obtained.

<2> In the piezoelectric element unit of <1> above, the first electrode is in contact with only the first side surface of the piezoelectric film, and the second electrode is in contact with only the second side surface of the piezoelectric film.

According to <2> above, since the bulk acoustic wave propagates in a direction parallel to the main surface of the substrate inside the piezoelectric film, in the piezoelectric element unit including the piezoelectric film, the first electrode, and the second electrode, by increasing a thickness of the piezoelectric film in a film thickness direction, it is possible to increase the density and reduce an area occupied by the piezoelectric element on the main surface of the substrate. Therefore, the piezoelectric element can be miniaturized and packaged at a high density, and as a result, the piezoelectric element unit suitable for miniaturization and high packaging density can be obtained.

<3> The piezoelectric element unit of <1> or <2> above further includes: a first spacer and a second spacer which are arranged on the substrate with the piezoelectric film interposed between the first spacer and the second spacer and are separated from the piezoelectric film. The first electrode is arranged between the piezoelectric film and the first spacer, the second electrode is arranged between the piezoelectric film and the second spacer, and the first spacer and the second spacer are made of the same material as the piezoelectric film.

According to <3> above, since the first spacer and the second spacer may be formed in the same process as the piezoelectric film, there is no need to add a new manufacturing process. By providing the first spacer and the second spacer, it is possible to secure a space for blocking the bulk acoustic wave from propagating to the substrate or the like, and to suppress damping of the vibration of the piezoelectric element.

<4> The piezoelectric element unit of <3> above further includes: a protective film arranged on the piezoelectric film. A space exists between the protective film and the first electrode in a region between the piezoelectric film and the first spacer, and a space exists between the protective film and the second electrode in a region between the piezoelectric film and the second spacer.

According to <4> above, the space operates to block the acoustic wave and can suppress the influence on the piezoelectric element unit when the resonator including the piezoelectric element unit is packaged.

<5> In the piezoelectric element unit of <1> above, a plurality of first electrodes and second electrodes are provided. Each of the plurality of first electrodes is in continuous contact with the first side surface of the piezoelectric film through an upper surface of the piezoelectric film to the second side surface of the piezoelectric film, each of the plurality of second electrodes is in continuous contact with the second side surface of the piezoelectric film through the upper surface of the piezoelectric film to the first side surface of the piezoelectric film, and the plurality of first electrodes and the plurality of second electrodes are alternately arranged in a direction perpendicular to a normal direction of the main surface and in a direction parallel to the first side surface.

According to <5> above, since each of the first electrode and the second electrode is in contact with the first side surface, the upper surface, and the second side surface of the piezoelectric film, the acoustic wave can be efficiently propagated between the electrodes.

<6> In the piezoelectric element unit of <1> above, a plurality of first electrodes in contact with only the first side surface and a plurality of second electrodes in contact with only the first side surface are provided. The plurality of first electrodes and the plurality of second electrodes are alternately arranged in a direction perpendicular to a normal direction of the main surface and in a direction parallel to the first side surface.

According to <6> above, since the first electrodes and the second electrodes (further, the wiring 106a and the wiring 106b) are arranged on only the side of the first side surface, it is possible to make an area occupied by the piezoelectric element on the main surface of the substrate smaller.

<7> In the piezoelectric element unit of any one of <1> to <6> above, a plurality of first electrodes and a plurality of second electrodes are provided. In a direction perpendicular to a film thickness direction of the piezoelectric film and a direction parallel to the first side surface, a distance between the first side surface of the first electrode and the second side surface of the second electrode oriented in the same direction as the first side surface of the first electrode is ½ of a pitch interval of the first electrode.

According to <7> above, the surface acoustic wave can be efficiently propagated between the electrodes by adjusting the arrangement of the first electrodes and the second electrodes.

<8> In the piezoelectric element unit of any one of <1> to <7> above, when viewed from the normal direction of the main surface, the piezoelectric film has a closed-annular shape, the first electrode is arranged along an outer periphery of the piezoelectric film, and the second electrode is arranged along an inner periphery of the piezoelectric film.

According to <8> above, it is possible to suppress the propagation of a bulk acoustic wave excited at electrode ends to both side surfaces of the piezoelectric film, the generation of a spurious wave which is an unnecessary wave reflected at the ends of the piezoelectric film, and the like. This makes it possible to efficiently excite and vibrate the piezoelectric element.

<9> In the piezoelectric element unit of any one of <1> to <8> above, the piezoelectric film has a first region and a second region arranged on the first region and having fewer crystal defects than the first region. The piezoelectric element unit further includes a sidewall insulating film that covers each of the first side surface and the second side surface in the first region.

According to <9> above, only a region with few crystal defects of the piezoelectric film can be used for the piezoelectric element. As a result, a radio frequency and a high electromechanical coupling coefficient can be obtained.

<10> In the piezoelectric element unit of any one of <1> to <9> above, the side surfaces of the piezoelectric film are exposed as non-polar surfaces, and the first electrode and the second electrode are in contact with the non-polar surfaces.

According to <10> above, it is possible to form the first electrode and the second electrode in a direction of the non-polar surfaces, thus obtaining a large electromechanical coupling coefficient.

<11> In the piezoelectric element unit of any one of <1> to <10> above, the piezoelectric film is oriented along a C-axis with respect to the substrate and extends in a direction perpendicular to a direction of the C-axis.

According to <11> above, it is possible to obtain a piezoelectric element unit that can suppress the damping of the bulk acoustic wave due to crystal defects and crystal grain boundaries, perform stable operation in a radio-frequency region, provide high piezoelectricity such as low loss, wide bandwidth, and high propagation speed, and have low temperature dependence.

<12> The piezoelectric element unit of any one of <1> to <11> above further includes an insulating film arranged on the upper surface of the piezoelectric film.

According to <12> above, it is possible to suppress damage caused by over-etching of the piezoelectric film when forming the first electrode and the second electrode.

<13> In the piezoelectric element unit of any one of <1> to <12> above, the first electrode and the second electrode include at least one selected from a group consisting of aluminum, molybdenum, titanium, tungsten, ruthenium, and gold.

According to <13> above, it is possible to obtain the first electrode and the second electrode that are stable and hardly react with the material of the piezoelectric film.

<14> In the piezoelectric element unit of any one of <1> to <13> above, the substrate is made of an aluminum nitride with or without at least one selected from a group consisting of scandium, ytterbium, magnesium, niobium, zirconium, titanium, hafnium, and yttrium.

<15> In the piezoelectric element unit of any one of <1> to <12> above, the substrate is made of one type of a single crystal or polycrystal selected from a group consisting of a lithium niobium oxide and a lithium tantalum oxide.

According to <14> and <15> above, since the substrate itself has excellent piezoelectric properties, the piezoelectric element including the piezoelectric film formed by processing the substrate can also have excellent piezoelectric properties.

<16> In a resonator including a plural number of the piezoelectric element unit of any one of <1> to <15> above, in two adjacent piezoelectric element units among the plurality of piezoelectric element units, a second electrode of one piezoelectric element unit is shared with a first electrode of the other piezoelectric element unit to connect the plurality of piezoelectric element units in series with each other.

<17> In a resonator including a plural number of the piezoelectric element unit of any one of <1> to <15> above, the plurality of piezoelectric element units are connected in parallel with each other, first electrodes of each of the plurality of piezoelectric element units are electrically connected to each other, and second electrodes of each of the plurality of piezoelectric element units are electrically connected to each other.

According to <16> and <17> above, since the plurality of piezoelectric element units suitable for miniaturization and high packaging density are provided, the resonator including the plurality of piezoelectric element units can also be miniaturized and have a high packaging density. Further, as the resonators are miniaturized and packaged at a high density, the manufacturing cost per resonator can be reduced.

### First Embodiment

A piezoelectric element unit 100 according to a first embodiment will be described with reference to the drawings.

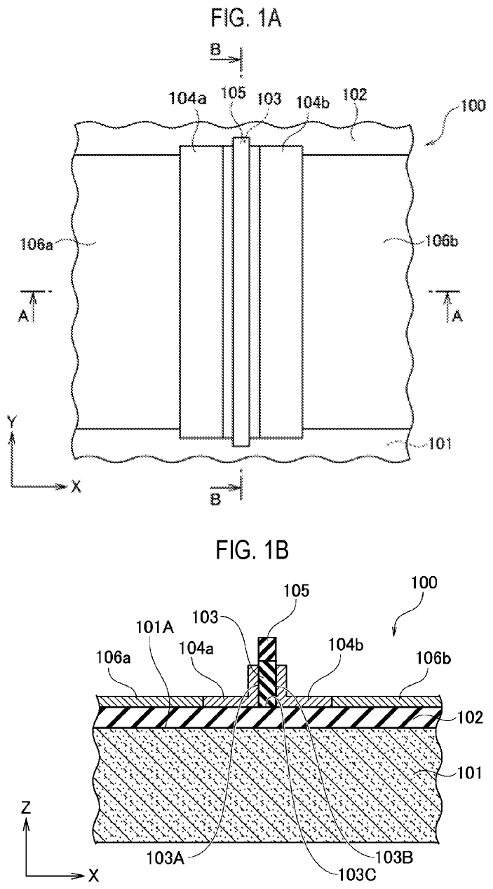

FIG. 1A is a partial top view illustrating the piezoelectric element unit 100. FIG. 1B is a partial cross-sectional view taken along line A-A in FIG. 1A. FIG. 1C is a partial cross-sectional view taken along line B-B in FIG. 1A. The piezoelectric element unit 100 is an example of a piezoelectric thin film resonant element (BAW element). The piezoelectric element unit 100 includes a substrate 101, an insulating film 102 on the substrate 101, a piezoelectric film 103 on the insulating film 102, electrodes 104a and 104b on the insulating film 102, an insulating film 105 on an upper surface of the piezoelectric film 103, a wiring 106a electrically connected to the electrode 104a, and a wiring 106b electrically connected to the electrode 104b.

The substrate 101 has a main surface 101A. The piezoelectric film 103 has a side surface 103A, a side surface 103B opposite to the side surface 103A, and a bottom surface 103C facing the main surface 101A via the insulating film 102 and connected to the side surfaces 103A and 103B. The electrode 104a is in contact with only the side surface 103A of the piezoelectric film 103, and the electrode 104b is in contact with only the side surface 103B of the piezoelectric film 103. That is, the electrode 104a is separated from the electrode 104b with the piezoelectric film 103 interposed therebetween. The piezoelectric film 103, the electrode 104a, and the electrode 104b are collectively called a piezoelectric element. The piezoelectric element utilizes resonance vibration (bulk acoustic wave) generated by lateral vibration of the piezoelectric film 103 in response to an input radio-frequency signal, which resonates in an X direction of the piezoelectric film 103.

In this embodiment, a direction in which the piezoelectric film 103 extends linearly is referred to as a Y direction, a direction perpendicular to the Y direction and parallel to the main surface 101A of the substrate 101 is referred to as an X direction, and a direction corresponding to a thickness of the substrate 101 is referred to as a Z direction. In other words, the Z direction is a direction perpendicular to each of the X and Y directions. Further, a direction in which the piezoelectric film 103 is located as viewed from the substrate 101 is referred to as an upward direction, and a direction in which the substrate 101 is located as viewed from the piezoelectric film 103 is referred to as a downward direction.

In this specification and the like, the expression “electrically connected” includes a case of being connected via “things having some electrical action.” Here, the expression “things having some electrical action” are not particularly limited as long as they enable transmission and reception of an electrical signal between connection objects. For example, the expression “things having some electrical action” includes electrodes, wirings, switching elements, resistive elements, inductors, capacitive elements, and other elements having other various functions.

A shape of the piezoelectric film 103 in this embodiment may be a pillar shape, and the piezoelectric film 103 is sandwiched between the electrodes 104a and 104b. The shape of the piezoelectric film 103 is not particularly limited as long as the piezoelectric film 103 vibrates in resonance. For example, an aspect ratio (X:Y) of the piezoelectric film 103 in the X and Y directions may be 1:10 to 200 or 1:10 to 50, or an aspect ratio (X:Z) of the piezoelectric film 103 in the X and Z directions may be 1:5 to 100 or 1:5 to 10. A length of the piezoelectric film 103 in the X direction is determined by a wavelength of a radio-frequency signal.

In the piezoelectric film 103, a propagation direction of an acoustic wave may be freely selected depending on how the piezoelectric film 103 is cut out. For example, the side surfaces 103A and 103B of the piezoelectric film 103 are exposed as non-polar surfaces. Thus, a large electromechanical coupling coefficient may be obtained. The side surfaces 103A and 103B of the piezoelectric film 103 may be cut out by selecting non-polar m-planes. Further, the influence of a piezoelectric field may be suppressed on the non-polar surfaces.

Further, by sandwiching the piezoelectric film 103 between the electrode 104a in contact with only the side surface 103A of the piezoelectric film 103 and the electrode 104b in contact with only the side surface 103B of the piezoelectric film 103, a bulk acoustic wave propagates in the X direction inside the piezoelectric film 103. Therefore, in the piezoelectric element, the area of a plane (YZ plane) perpendicular to the propagation direction of the bulk acoustic wave may be formed large, which makes it possible to reduce the area occupied by the piezoelectric element in the XY plane. This makes it possible to miniaturize the piezoelectric element and package the same at a high density. As a result, a piezoelectric element unit suitable for miniaturization and high packaging density may be obtained.

Further, in a piezoelectric element in the related art, an electrode and a piezoelectric film are stacked in the Z direction. For this reason, a bulk acoustic wave propagate in the Z direction inside the piezoelectric film, causing the piezoelectric element to vibrate in the Z direction. In order to suppress the attenuation of such a vibration, it is necessary to form a space (hollow portion) in a substrate that supports the piezoelectric element. However, in this embodiment, the bulk acoustic wave propagates in the X direction inside the piezoelectric film 103, causing the piezoelectric element to vibrate in the X direction. A space for blocking the bulk acoustic wave from propagating to the substrate or the like exists on the side surface of the piezoelectric element. This space suppresses damping of the vibration of the piezoelectric element in the X direction. The space may be formed without adding the processing process used in the related art, which makes it possible to reduce the manufacturing cost.

The piezoelectric film 103 is composed of, for example, monocrystal or polycrystal of aluminum nitride (AlN), zinc oxide (ZnO), lithium niobium oxide (LiNbO₃), lithium tantalum oxide (LiTaO₃), and lead zirconate titanate (Pb(Zr,Ti)O₃;PZT). A filter in a radio-frequency band is required to have a wide bandwidth, high propagation velocity, and temperature stability. Aluminum nitride, which has a high piezoelectric constant, a high propagation velocity, and a small temperature coefficient, may be used as a material of the piezoelectric film 103.

The piezoelectric film 103 may be oriented along a C-axis with respect to the substrate and may extend in a direction perpendicular to the C-axis direction (Z direction). In particular, an aluminum nitride film having a crystal region highly oriented along the C-axis of a highly-crystalline single crystal has few crystal defects and grain boundaries. Therefore, when the piezoelectric film 103 includes the aluminum nitride film having a crystal region highly oriented along the C-axis, it is possible to obtain a piezoelectric element unit that can suppress the damping of the bulk acoustic wave due to crystal defects and crystal grain boundaries, perform stable operation in a radio-frequency region, provide high piezoelectricity such as low loss, wide bandwidth, and high propagation speed, and have low temperature dependence.

If the full width at half maximum (FWHM) at (002) diffraction peak of the aluminum nitride film is smaller, it means that the orientation is higher. For example, in this embodiment, “highly oriented along the C-axis” means that the FWHM is less than 1.00 degree.

From the viewpoint of high orientation, the thickness of the piezoelectric film 103 may be, for example, 70 nm or more, more specifically 100 nm or more.

The piezoelectric film 103 oriented along the C-axis may be formed using a CVD (Chemical Vapor Deposition) method or a MBE (Molecular Beam Epitaxy) method, more specifically using a MOCVD (Metal Organic Chemical Vapor Deposition) method from the viewpoint of highly orienting crystals along the C-axis.

Further, since the crystallinity of a surface on which the piezoelectric film 103 is formed contributes to the crystallinity of the piezoelectric film 103, the substrate 101 or the insulating film 102 having high crystallinity is used. The substrate 101 or the insulating film 102 acts as a seed crystal for the aluminum nitride film, and the piezoelectric film 103 having crystal regions highly oriented along the C-axis may be formed by crystal growth using the seed crystals as nuclei.

The substrate 101 is for supporting the piezoelectric element (the piezoelectric film 103 and the electrodes 104a and 104b) and the like. Examples of the substrate 101 may include a silicon substrate, an SOI substrate, a SiC substrates, a sapphire substrate, and the like. If the main surface 101A of the substrate 101 has fine unevenness, it may hinder the crystal growth of the piezoelectric film 103. Therefore, the main surface 101A of the substrate 101 needs to be flattened by a CMP (Chemical Mechanical Polishing) method or the like.

Further, the insulating film 102 may be provided on the substrate 101 to reduce the influence of fine unevenness on the main surface 101A. Examples of the insulating film 102 may include inorganic insulating films such as a zirconium oxide film, a tantalum oxide film, a silicon oxide film, and a silicon nitride film. From the viewpoint of crystal growth of the piezoelectric film 103, the insulating film 102 may use highly crystalline zirconium oxide and tantalum oxide.

The electrodes 104a and 104b are electrodes for applying an electric field to the piezoelectric film 103. The electrodes 104a and 104b are in contact with the side surfaces 103A and 103B of the piezoelectric film 103, which are non-polar surfaces, respectively, and may suppress the influence of the piezoelectric field. Materials of the electrodes 104a and 104b may include, for example, at least one of aluminum, molybdenum, titanium, tungsten, ruthenium, and gold. These materials are stable materials that do not easily react with the material of the piezoelectric film 103.

In a case where the resistance of the electrodes 104a and 104b is high and parasitic impedance is high, the wirings 106a and 106b may be provided. Examples of materials of the wirings 106a and 106b may include aluminum, copper, silver, palladium, iridium, platinum, and gold. Further, from the viewpoint of reducing the parasitic impedance, the wirings 106a and 106b may be thickly formed.

The insulating film 105 is provided on the piezoelectric film 103. The insulating film 105 may suppress damage due to over-etching of the piezoelectric film 103 when forming the electrodes 104a and 104b by etching in the Z direction. When the electrodes 104a and 104b are formed using an etching method that causes less damage to the piezoelectric film 103, the insulating film 105 may not be provided.

According to this embodiment, the bulk acoustic wave propagates in the direction (X direction) parallel to the main surface 101A of the substrate 101 inside the piezoelectric film. Therefore, in the piezoelectric element including the piezoelectric film 103 and the electrodes 104a and 104b, when the amount of excavation of the piezoelectric film 103 (thickness in the Z direction) is increased, the density may be increased, which makes it possible to reduce the area occupied by the piezoelectric element on the main surface 101A (XY plane) of the substrate 101. Therefore, the piezoelectric element may be miniaturized and packaged at a high density. As a result, the piezoelectric element unit 100 suitable for miniaturization and high packaging density may be obtained.

### First Modification

A configuration of a piezoelectric element unit 100A according to a first modification will be described.

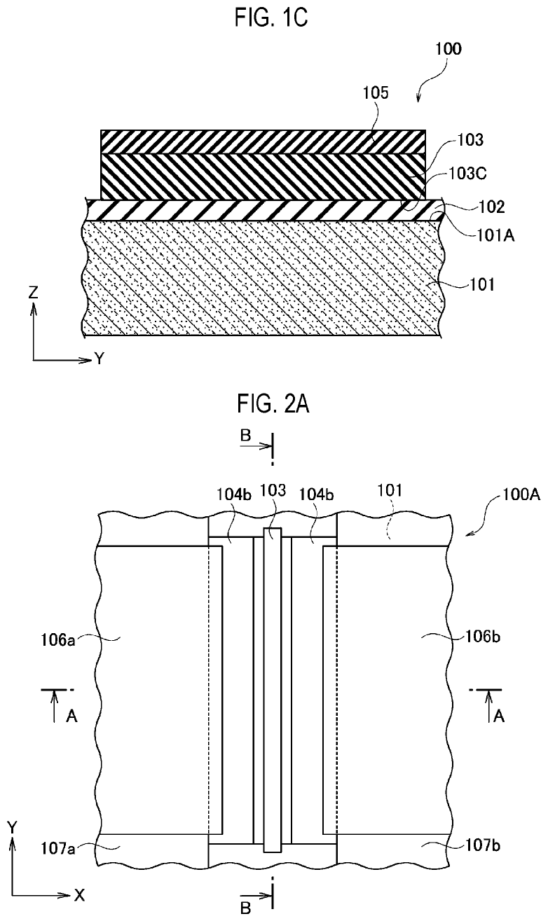

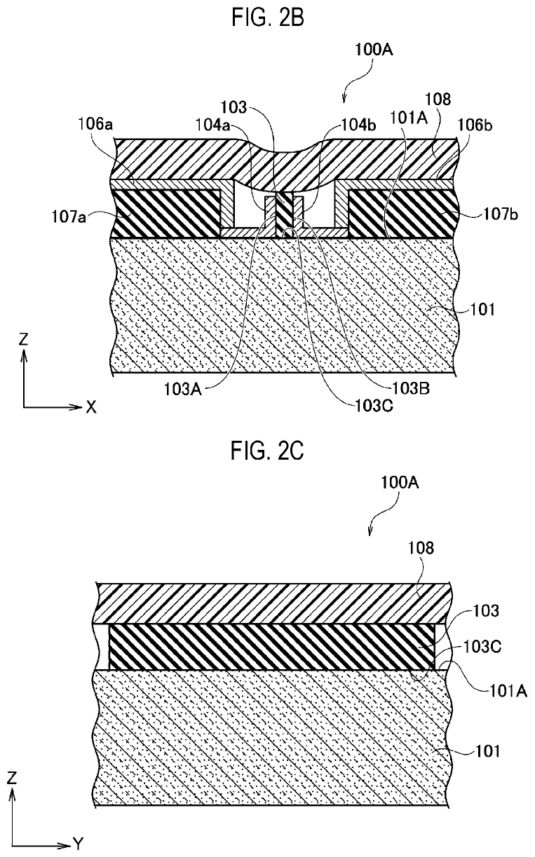

FIG. 2A is a partial top view illustrating the piezoelectric element unit 100A. FIG. 2B is a partial cross-sectional view taken along line A-A in FIG. 2A. FIG. 2C is a partial cross-sectional view taken along line B-B in FIG. 2A. The piezoelectric element unit 100A is an example of a BAW element. The piezoelectric element unit 100A includes a substrate 101, a piezoelectric film 103 on the substrate 101, spacers 107a and 107b provided to be separated from the piezoelectric film 103 on the substrate 101, electrodes 104a and 104b on the substrate 101, a wiring 106a electrically connected to the electrode 104a, a wiring 106b electrically connected to the electrode 104b, and a protective film 108 for covering the piezoelectric film 103, the wiring 106a, the wiring 106b, and the like. The electrode 104a is arranged between the piezoelectric film 103 and the spacer 107a, and the electrode 104b is arranged between the piezoelectric film 103 and the spacer 107b. For ease of understanding, the protective film 108 is not shown in FIG. 2A. The spacers 107a and 107b are made of the same material as the piezoelectric film 103. The piezoelectric element unit 100A according to this modification is different from the piezoelectric element unit 100 shown in FIGS. 1A to 1C in that the former provides the spacer 107a, the spacer 107b, and the protective film 108. In this modification, the above description is used for common points with the piezoelectric element unit 100 shown in FIGS. 1A to 1C, and different points will be described below.

In the piezoelectric element unit 100, only the piezoelectric film in the piezoelectric element region is left and the rest is removed. In contrast, in the piezoelectric element unit 100 110A of this modification, the piezoelectric film is removed only in the peripheral region of the piezoelectric element region, and the piezoelectric film (the spacers 107a and 107b) other than the piezoelectric element region may function as a spacer between the substrate 101 and the protective film 108. Further, the spacers 107a and 107b may be connected to (integrated with) the piezoelectric film 103 in a direction in which the bulk acoustic wave does not propagate.

According to this modification, it is possible to obtain the piezoelectric element unit 100A suitable for miniaturization and high packaging density in the same manner as the above-described piezoelectric element unit 100. Further, since the spacers 107a and 107b are made of the same material as the piezoelectric film 103 and may be formed in the same process as the piezoelectric film 103, it is possible to form the spacers 107a and 107b without adding a new manufacturing process. By providing the spacers 107a and 107b, it is possible to secure a space for blocking the bulk acoustic wave from propagating to the substrate 101 and the like, and to suppress damping of the vibration of the piezoelectric element.

### Second Modification

A configuration of a piezoelectric element unit 100B according to a second modification will be described.

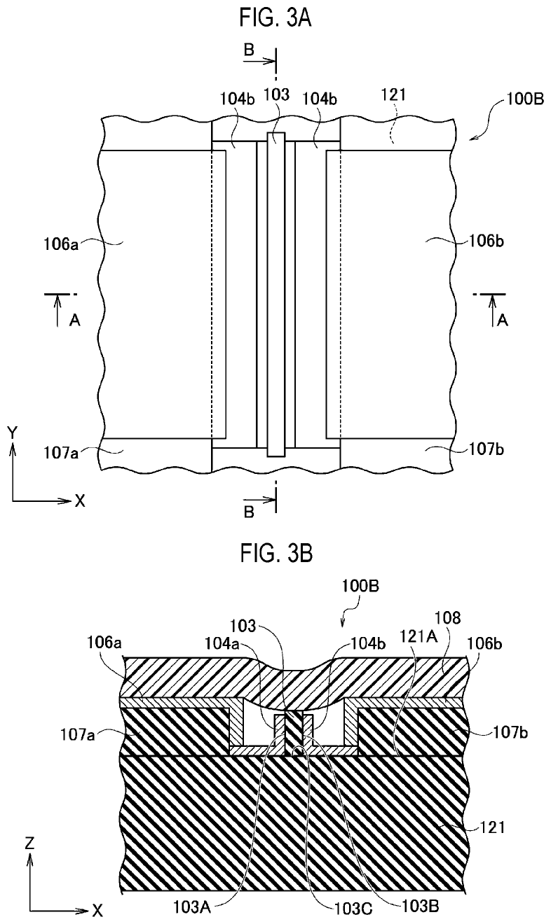

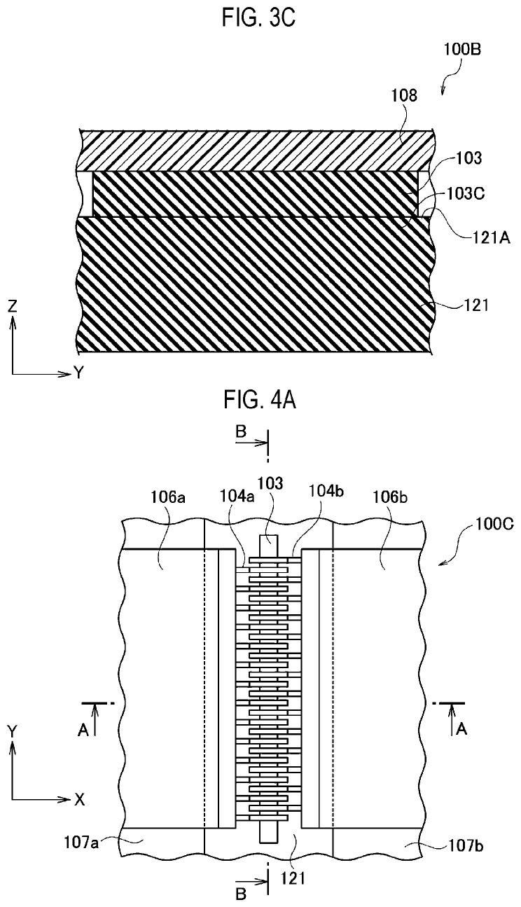

FIG. 3A is a partial top view illustrating the piezoelectric element unit 100B. FIG. 3B is a partial cross-sectional view taken along line A-A in FIG. 3A. FIG. 3C is a partial cross-sectional view taken along line B-B in FIG. 3A. The piezoelectric element unit 100B is an example of a BAW element. The piezoelectric element unit 100B includes a substrate 121, a piezoelectric film 103 on the substrate 121, spacers 107a and 107b separated from the piezoelectric film 103 on the substrate 121, electrodes 104a and 104b on the substrate 121, a wiring 106a electrically connected to the electrode 104a, a wiring 106b electrically connected to the electrode 104b, and a protective film 108 covering the piezoelectric film 103, the wiring 106a, the wiring 106b, and the like. The electrode 104a is arranged between the piezoelectric film 103 and the spacer 107a, and the electrode 104b is arranged between the piezoelectric film 103 and the spacer 107b. For ease of understanding, the protective film 108 is not shown in FIG. 3A. The piezoelectric film 103 and the spacers 107a and 107b are made of the same material as the substrate 121. The piezoelectric element unit 100B according to this modification is different from the piezoelectric element unit 100A shown in FIGS. 2A to 2C in that the substrate 121 is provided instead of the substrate 101. In this modification, the above description is used for common points with the piezoelectric element unit 100A shown in FIGS. 2A to 2C, and different points will be described below.

In the piezoelectric element unit 100A, the piezoelectric film is formed using a material different from that of the substrate. In contrast, in the piezoelectric element unit 100B of this modification, the substrate 121 is processed to form the piezoelectric film 103 and the spacers 107a and 107b. Further, the spacers 107a and 107b may be connected to (integrated with) the piezoelectric film 103 in a direction in which the bulk acoustic wave does not propagate.

The substrate 121 has a main surface 121A. The substrate 121 is made of, for example, single crystal or polycrystal of lithium niobium oxide, lithium tantalum oxide, and the like. Since these materials have excellent piezoelectric properties, the piezoelectric element including the piezoelectric film 103 formed by processing the substrate 121 also has excellent piezoelectric properties.

Further, the substrate 121 may be made of aluminum nitride with or without at least one selected from the group consisting of scandium, ytterbium, magnesium, niobium, zirconium, titanium, hafnium, and yttrium. Since these materials have excellent piezoelectric properties, the piezoelectric element including the piezoelectric film 103 formed by processing the substrate 121 also has excellent piezoelectric properties.

According to this modification, it is possible to obtain the piezoelectric element unit 100B suitable for miniaturization and high packaging density in the same manner as the above-described piezoelectric element unit 100. Further, since the piezoelectric film 103 and the spacers 107a and 107b are made of the same material as the substrate 121 and may be formed by processing the substrate 121 in the same process, it is possible to eliminate the need to form a film that functions as the piezoelectric film 103 and the spacers 107a and 107b as compared to the first modification. This makes it possible to reduce a process of manufacturing the piezoelectric element unit. As in the first modification, by providing the spacers 107a and 107b, it is possible to secure a space for blocking the bulk acoustic waves from propagating to the substrate 101 and the like, and to suppress damping of the vibration of the piezoelectric element.

### Second Embodiment

A piezoelectric element unit 100C according to a second embodiment will be described with reference to the drawings.

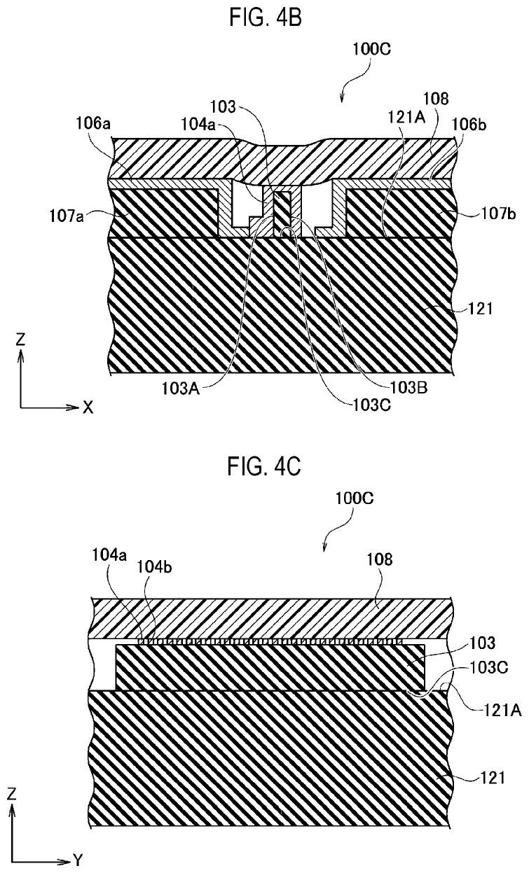

FIG. 4A is a partial top view illustrating the piezoelectric element unit 100C. FIG. 4B is a partial cross-sectional view taken along line A-A in FIG. 4A. FIG. 4C is a partial cross-sectional view taken along line B-B in FIG. 4A. The piezoelectric element unit 100C is an example of a surface acoustic wave element (SAW element). The piezoelectric element unit 100C includes a substrate 121, a piezoelectric film 103 on the substrate 121, spacers 107a and 107b separated from the piezoelectric film 103 on the substrate 121, a plurality of electrodes 104a and a plurality of electrodes 104b on the substrate 121, a wiring 106a electrically connected to each electrode 104a, a wiring 106b electrically connected to each electrode 104b, and a protective film 108 covering the piezoelectric film 103, the wirings 106a and 106b, and the like. Each electrode 104a is in continuous contact with the side surface 103A of the piezoelectric film 103 through the upper surface of the piezoelectric film 103 to the side surface 103B thereof, and each electrode 104b is in continuous contact with the side surface 103B of the piezoelectric film 103 through the upper surface of the piezoelectric film 103 to the side surface 103A thereof. Each electrode 104a and each electrode 104b are alternately arranged in a direction perpendicular to the normal direction of the main surface 121A of the substrate 121 and a direction parallel to the side surface 103A (that is, the Y direction). For ease of understanding, the protective film 108 is not shown in FIG. 4A. The piezoelectric film 103 and the spacers 107a and 107b are made of the same material as the substrate 121. The piezoelectric element unit 100C according to this embodiment is different from the above-described piezoelectric element unit 100B shown in FIGS. 3A to 3C in that a plurality of electrodes 104a and 104b are provided and the electrodes 104a and 104b are in contact with the side surfaces 103A and 103B of the piezoelectric film 103, respectively. In this embodiment, the above description is used for common points with the piezoelectric element unit 100B shown in FIGS. 3A to 3C, and different points will be described below.

The piezoelectric element (the piezoelectric film 103 and the electrodes 104a and 104b) in this embodiment uses the resonance characteristics of a surface acoustic wave excited by the electrodes 104a and 104b. When a signal is input to the electrode 104a from the outside through the wiring 106a, the surface acoustic wave excited by the electrode 104a propagates through the side surfaces 103A and 103B of the piezoelectric film 103, and the signal is output to the outside through the wiring 106b. The electrodes 104a and 104b may be comb-like electrodes (interdigital transducers (IDTs)) because they can efficiently excite the surface acoustic wave.

Since the electrodes 104a and 104b are in contact with the side surface 103A of the piezoelectric film 103, the upper surface of the piezoelectric film 103, and the side surface 103B of the piezoelectric film 103, the surface acoustic waves may be efficiently propagated between the electrodes. In order to more efficiently propagate the surface acoustic wave between the electrodes, the side surfaces 103A and 103B of the piezoelectric film 103 need to be widened, that is, in the piezoelectric element, the area of a plane perpendicular to the propagation direction of the surface acoustic wave needs to be formed large. This makes it possible to reduce the area occupied by the piezoelectric element in the XY plane. Therefore, the piezoelectric element can be miniaturized and packaged at a high density, and as a result, the piezoelectric element unit 100C suitable for miniaturization and high packaging density can be obtained.

### First Modification

A configuration of a piezoelectric element unit 100D according to a first modification will be described.

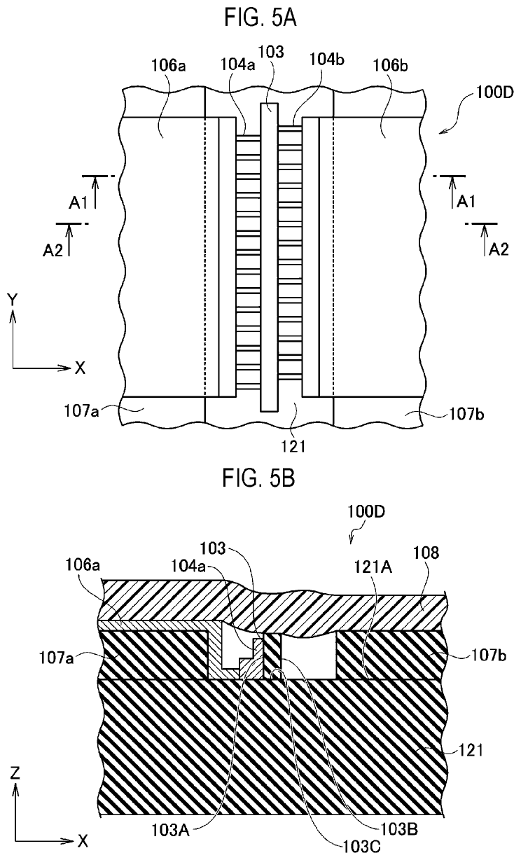

FIG. 5A is a partial top view illustrating the piezoelectric element unit 100D. FIG. 5B is a partial cross-sectional view taken along line A1-A1 in FIG. 5A. FIG. 5C is a partial cross-sectional view taken along line A2-A2 in FIG. 5A. The piezoelectric element unit 100D is an example of a SAW element. The piezoelectric element unit 100D includes a substrate 121, a piezoelectric film 103 on the substrate 121, spacers 107a and 107b separated from the piezoelectric film 103 on the substrate 121, a plurality of electrodes 104a and a plurality of electrodes 104b on the substrate 121, a wiring 106a electrically connected to each electrode 104a, a wiring 106b electrically connected to each electrode 104b, and a protective film 108 covering the piezoelectric film 103, the wirings 106a and 106b, and the like. Each electrode 104a is in contact with only the side surface 103A of the piezoelectric film 103, and each electrode 104b is in contact with only the side surface 103B of the piezoelectric film 103. The piezoelectric film 103 and the spacers 107a and 107b are made of the same material as the substrate 121. The piezoelectric element unit 100D according to this modification is different from the above-described piezoelectric element unit 100C shown in FIGS. 4A to 4C in that the electrode 104a is in contact with only the side surface 103A of the piezoelectric film 103 and the electrode 104b is in contact with only the side surface 103B of the piezoelectric film 103.

According to this modification, like the piezoelectric element unit 100C, the piezoelectric elements can be miniaturized and packaged at a high density, and as a result, the piezoelectric element unit 100D suitable for miniaturization and high packaging density can be obtained.

### Second Modification

A configuration of a piezoelectric element unit 100E according to a second modification will be described.

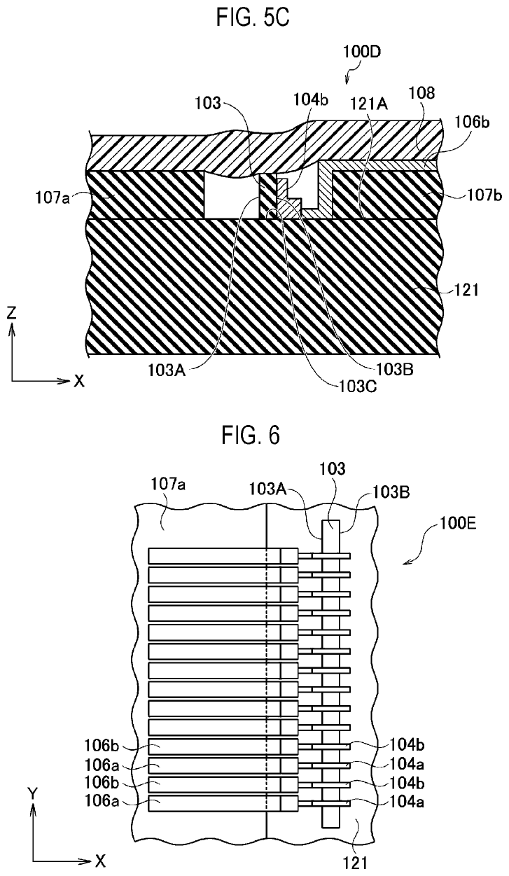

FIG. 6 is a partial top view illustrating the piezoelectric element unit 100E. The piezoelectric element unit 100E is an example of a SAW element. The piezoelectric element unit 100E includes a substrate 121, a piezoelectric film 103 on the substrate 121, a spacer 107a separated from the piezoelectric film 103 on the substrate 121, a plurality of electrodes 104a and a plurality of electrodes 104b on the substrate 121, a wiring 106a electrically connected to each electrode 104a, a wiring 106b electrically connected to each electrode 104b, and a protective film 108 covering the piezoelectric film 103, the wirings 106a and 106b, and the like. Each electrode 104a and each electrode 104b are in continuous contact with the side surface 103A of the piezoelectric film 103 to the side surface 103B thereof. Each electrode 104a and each electrode 104b are alternately arranged in a direction perpendicular to the normal direction of the main surface 121A of the substrate 121 and a direction parallel to the side surface 103A (that is, the Y direction). For ease of understanding, the protective film 108 is not shown in FIG. 6. The piezoelectric film 103 and the spacer 107a are made of the same material as the substrate 121. The piezoelectric element unit 100E according to this modification is different from the above-described piezoelectric element unit 100C shown in FIGS. 4A to 4C in that the wirings 106a and 106b are arranged on only the side surface 103A.

According to this modification, since the wirings 106a and 106b are arranged on only the side surface 103A, the area occupied by the piezoelectric elements in the XY plane can be further reduced, and the piezoelectric element can be miniaturized and packaged at a high density in the same manner as the piezoelectric element unit 100C. As a result, the piezoelectric element unit 100E suitable for miniaturization and high packaging density can be obtained.

### Third Modification

A configuration of a piezoelectric element unit 100F according to a third modification will be described.

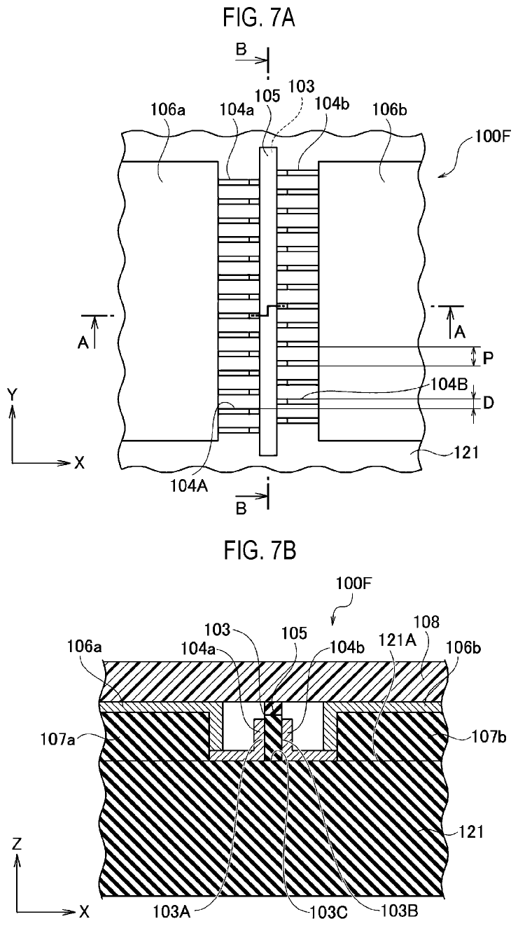

FIG. 7A is a partial top view illustrating the piezoelectric element unit 100F. FIG. 7B is a partial cross-sectional view taken along line A-A of FIG. 7A. FIG. 7C is a partial cross-sectional view taken along line B-B in FIG. 7A. The piezoelectric element unit 100F is an example of a SAW element. The piezoelectric element unit 100F includes a substrate 121, a piezoelectric film 103 on the substrate 121, spacers 107a and 107b separated from the piezoelectric film 103 on the substrate 121, a plurality of electrodes 104a and a plurality of electrodes 104b on the substrate 121, a wiring 106a electrically connected to each electrode 104a, a wiring 106b electrically connected to each electrode 104b, an insulating film 105 on the upper surface of the piezoelectric film 103, and a protective film 108 covering the piezoelectric film 103, the wirings 106a and 106b, and the like. Each electrode 104a is in contact with only the side surface 103A of the piezoelectric film 103, and each electrode 104b is in contact with only the side surface 103B of the piezoelectric film 103. Each electrode 104a and each electrode 104b are alternately arranged in a direction perpendicular to the normal direction of the main surface 121A of the substrate 121 and a direction parallel to the side surface 103A (that is, the Y direction). Further, in a direction perpendicular to the film thickness direction of the piezoelectric film 103 and a direction parallel to the side surface 103A, that is, in the Y direction, a distance D between the side surface 104A of the electrode 104a and the side surface 104B of the electrode 104b facing in the same direction as the side surface 104A is ½ of a pitch interval P of the electrode 104a. The piezoelectric film 103 and the spacers 107a and 107b are made of the same material as the substrate 121. The piezoelectric element unit 100F according to this modification is different from the above-described piezoelectric element unit 100D shown in FIGS. 5A to 5C in that the former includes the electrodes 104a and 104b and the insulating film 105.

When the electrodes 104a and 104b have the same pitch period, by adjusting the position of arrangement of the electrode 104a to ½ of a pitch period λ, of the electrode 104a, that is, by adjusting the distance D to ½ of the pitch interval P of the electrode 104b, the surface acoustic wave can be efficiently propagated between the electrodes from the side surfaces 103A and 103B of the piezoelectric film 103.

According to this modification, by arranging the electrodes 104a and 104b as described above, the surface acoustic wave can be efficiently propagated between the electrodes, and further, similarly to the piezoelectric element unit 100C, the piezoelectric element can be miniaturized and packaged at a high density, and as a result, the piezoelectric element unit 100F suitable for miniaturization and high packaging density can be obtained.

### [Resonator]

Next, a configuration of a resonator 100G including a plurality of piezoelectric element units according to this embodiment will be described.

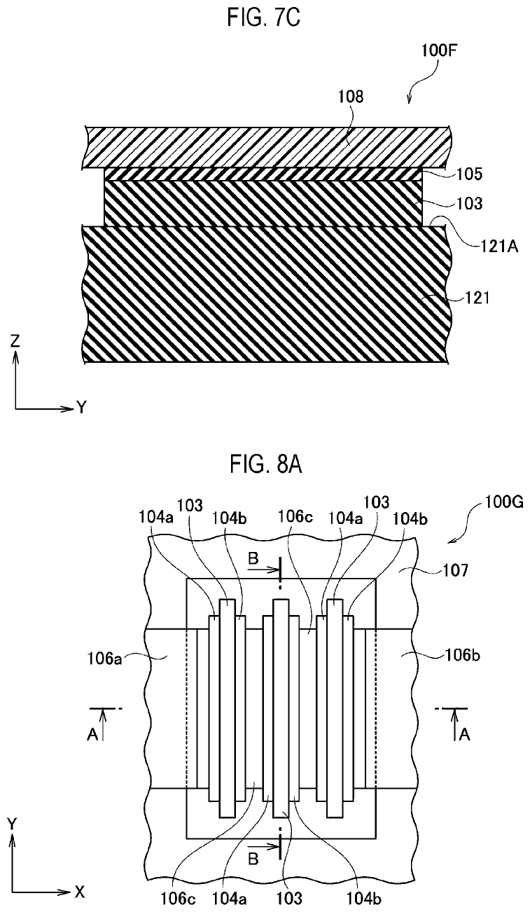

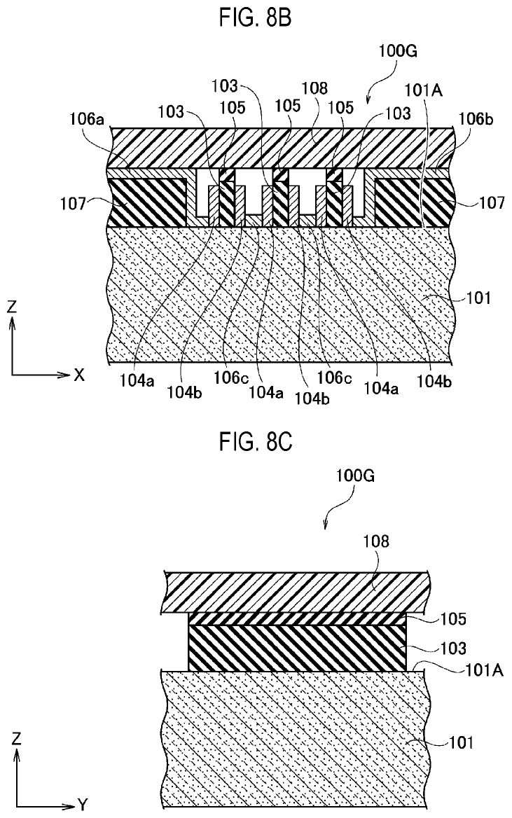

FIG. 8A is a partial top view illustrating the resonator 100G. FIG. 8B is a partial cross-sectional view taken along line A-A in FIG. 8A. FIG. 8C is a partial cross-sectional view taken along line B-B of FIG. 8A. The resonator 100G includes the plurality of piezoelectric element units 100A described above connected in series to each other. Specifically, the resonator 100G includes a substrate 101, a plurality of piezoelectric films 103 on the substrate 101, a spacer 107 on the substrate 101, a plurality of electrodes 104a and a plurality of electrodes 104b on the substrate 101, a wiring 106a electrically connected to the electrode 104a closest to the spacer 107 side, a wiring 106b electrically connected to the electrode 104b closest to the spacer 107 side, a plurality of wirings 106c electrically connected to the electrode 104a and the electrode 104b between two adjacent piezoelectric films 103, and a protective film 108 covering the piezoelectric film 103, the wirings 106a and 106b, and the like. An insulating film 105 is provided on the upper surface of the piezoelectric film 103 of the piezoelectric element unit 100A. For ease of understanding, the protective film 108 is not shown in FIG. 8A.

In the resonator 100G, in two adjacent piezoelectric element units among the plurality of piezoelectric element units 100A, the electrode 104b of one piezoelectric element unit 100A is shared with the electrode 104a of the other piezoelectric element unit 100A via a wiring 106c.

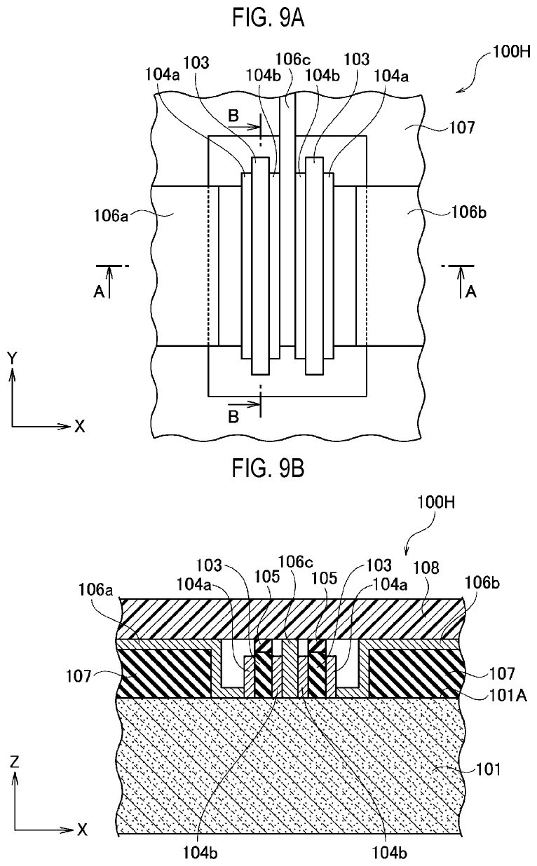

Further, the plurality of piezoelectric element units 100A may be connected in parallel to each other. FIG. 9A is a partial top view illustrating a resonator 100H. FIG. 9B is a partial cross-sectional view taken along line A-A in FIG. 9A. FIG. 9C is a partial cross-sectional view taken along line B-B in FIG. 9. The resonator 100H includes a substrate 101, a plurality of piezoelectric films 103 on the substrate 101, a spacer 107 on the substrate 101, a plurality of electrodes 104a and a plurality of electrodes 104b on the substrate 101, a wiring 106a electrically connected to the electrode 104a closest to the spacer 107 side, a wiring 106b electrically connected to the other electrode 104a farthest in the X direction, which is different from the electrode 104a electrically connected to the wiring 106a, and a plurality of wirings 106c electrically connected to two electrodes 104b between two adjacent piezoelectric films 103, and a protective film 108 covering the piezoelectric films 103, the wirings 106a, 106b, and 106c, and the like. An insulating film 105 is provided on the piezoelectric film 103 of the piezoelectric element unit 100A. For ease of understanding, the protective film 108 is not shown in FIG. 9A.

The resonator 100H electrically connects the electrodes 104a of the plurality of piezoelectric element units 100A to each other via the wirings 106a and 106b and electrically connects the electrodes 104b of the plurality of piezoelectric element units 100A to each other via the wirings 106c. Here, an example in which the piezoelectric element unit 100A is used for the resonator is shown, but the present disclosure is not limited thereto, and any piezoelectric element unit suitable for miniaturization and high packaging density may be used for the resonator.

Since the resonator 100G and the resonator 100H have a plurality of piezoelectric element units suitable for miniaturization and high packaging density, the resonator 100G and the resonator 100H having the plurality of piezoelectric element units can also be miniaturized and packaged at a high density. Further, as the resonators 100G and 100H are miniaturized and packaged at a high density, the manufacturing cost per resonator can be reduced.

### [Closed-Annular Piezoelectric Element Unit]

Next, a configuration of a piezoelectric element unit 100I, which is a closed-annular piezoelectric element unit, will be described.

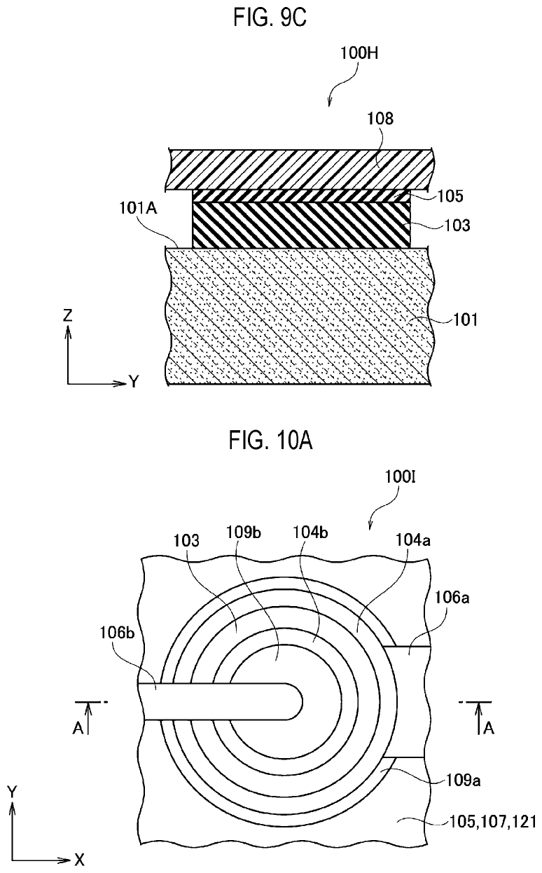

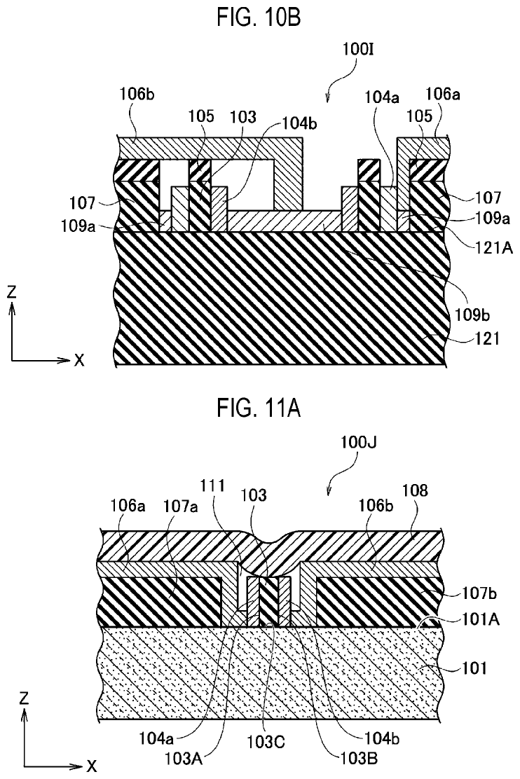

FIG. 10A is a partial top view illustrating the piezoelectric element unit 100I. FIG. 10B is a partial cross-sectional view taken along line A-A in FIG. 10A. The piezoelectric element unit 100I is an example of a BAW element. The piezoelectric element unit 100I includes a substrate 121, a piezoelectric film 103 on the substrate 121, a spacer 107 on the substrate 121, electrodes 104a and 104b on the substrate 121, a wiring 109a electrically connected to the electrode 104a, a wiring 109b electrically connected to the electrode 104b, an insulating film 105 on the upper surface of the piezoelectric film 103, a wiring 106a electrically connected to the wiring 109a, and a wiring 106b electrically connected to the wiring 109b. The piezoelectric element unit 100I is different from the above-described piezoelectric element unit 100B shown in FIGS. 3A to 3C in that the piezoelectric film 103 has a closed-annular shape. In this configuration, the above description is used for common points with the piezoelectric element unit 100B shown in FIGS. 3A to 3C, and different points will be described below.

The piezoelectric film 103 has a closed-annular shape when viewed from the normal direction (the Z direction) of the main surface 121A of the substrate 121. As used herein, the term “closed-annular shape” refers to an annular shape having continuous outer and inner peripheries without ends. FIG. 10A shows the piezoelectric film 103 having a circular closed-annular shape, but the present disclosure is not limited thereto. For example, in addition to such a circle, polygons such as an ellipse, a triangle, and a quadrilateral may be used for the piezoelectric film 103.

The electrode 104a is arranged along the outer periphery of the closed-annular piezoelectric film 103, and the electrode 104b is arranged along the inner periphery of the closed-annular piezoelectric film 103. Since the piezoelectric film 103 has no ends on its outer and inner peripheries, it is possible to suppress the propagation of a bulk acoustic wave excited at electrode ends to both side surfaces of the piezoelectric film 103, the generation of a spurious wave which is an unnecessary wave reflected at the ends of the piezoelectric film 103, and the like. This makes it possible to efficiently excite and vibrate the piezoelectric element.

Although the piezoelectric element unit 100I is shown as an example of the BAW element, the present disclosure is not limited thereto, and the piezoelectric element unit 100I may be a closed-annular piezoelectric element unit which is a SAW element. In the case of the SAW element, since the surface acoustic wave always propagates between the electrodes, the piezoelectric element can be excited and vibrated efficiently.

The piezoelectric element unit 100I, which is a closed-annular piezoelectric element unit, can efficiently excite and vibrate the piezoelectric element as described above. Further, similarly to the piezoelectric element unit 100C, the piezoelectric elements can be miniaturized and packaged at a high density, and as a result, the piezoelectric element unit 100I suitable for miniaturization and high packaging density can be obtained.

### [Space]

Next, a space that exists between a protective film and an electrode in a piezoelectric element unit will be described.

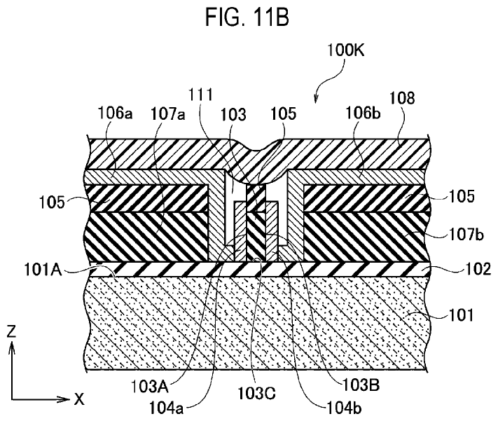

FIG. 11A is a partial cross-sectional view illustrating a piezoelectric element unit 100J. The piezoelectric element unit 100J is an example of a BAW element. The piezoelectric element unit 100J includes a substrate 101, a piezoelectric film 103 on the substrate 101, spacers 107a and 107b separated from the piezoelectric film 103 on the substrate 101, electrodes 104a and 104b on the substrate 101, a wiring 106a electrically connected to the electrode 104a, a wiring 106b electrically connected to the electrode 104b, and a protective film 108 covering the piezoelectric film 103, the wirings 106a and 106b, and the like. The electrode 104a is arranged between the piezoelectric film 103 and the spacer 107a, and the electrode 104b is arranged between the piezoelectric film 103 and the spacer 107b. A space 111 exists between the protective film 108 and the electrode 104a in a region between the piezoelectric film 103 and the spacer 107a, and a space 111 exists between the protective film 108 and the electrode 104b in a region between the piezoelectric film 103 and the spacer 107b.

FIG. 11B is a partial cross-sectional view illustrating a piezoelectric element unit 100K. The piezoelectric element unit 100K is an example of a BAW element. The piezoelectric element unit 100K includes a substrate 101, an insulating film 102 on the substrate 101, a piezoelectric film 103 on the insulating film 102, spacers 107a and 107b separated from the piezoelectric film 103 on the insulating film 102, electrodes 104a and 104b on the insulating film 102, insulating films 105 on the piezoelectric film 103, the spacer 107a, and the spacer 107b, a wiring 106a electrically connected to the electrode 104a, a wiring 106b electrically connected to the electrode 104b, and a protective film 108 covering the piezoelectric film 103, the wirings 106a and 106b, and the like. The electrode 104a is arranged between the piezoelectric film 103 and the spacer 107a, and the electrode 104b is arranged between the piezoelectric film 103 and the spacer 107b. A space 111 exists between the protective film 108 and the electrode 104a in a region between the piezoelectric film 103 and the spacer 107a, and a space 111 exists between the protective film 108 and the electrode 104b in a region between the piezoelectric film 103 and the spacer 107b. The insulating films 105 on the spacer 107a and the spacer 107b also function as spacers.

Since the piezoelectric element is formed large in the Z direction and occupies a small area in the XY plane, the space 111 is not filled with the protective film 108 when the protective film 108 is formed using a CVD method or a sputtering method. The space 111 operates to block the propagation of an acoustic wave (here, a bulk acoustic waves) to the substrate 101 and the like, and can suppress the influence on the piezoelectric element unit when packaging a resonator including the piezoelectric element unit.

### [Sidewall Insulating Film]

Next, a piezoelectric element unit having a sidewall insulating film will be described.

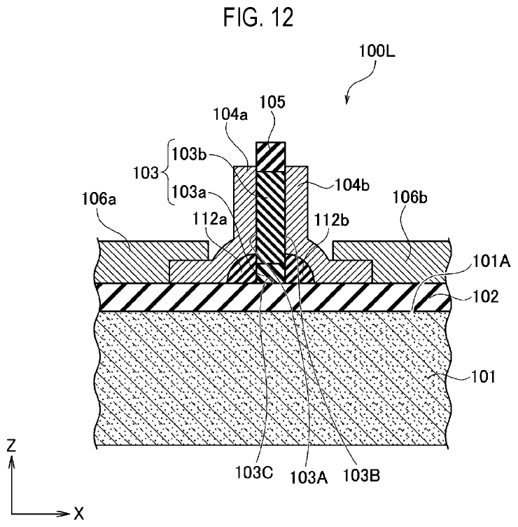

FIG. 12 is a partial cross-sectional view illustrating a piezoelectric element unit 100L. The piezoelectric element unit 100L is an example of a BAW element. The piezoelectric element unit 100L includes a substrate 101, an insulating film 102 on the substrate 101, a piezoelectric film 103 on the insulating film 102, a sidewall insulating film 112a and a sidewall insulating film 112b on the insulating film 102, an electrode 104a on the insulating film 102 and the sidewall insulating film 112a, an electrode 104b on the insulating film 102 and the sidewall insulating film 112b, an insulating film 105 on the upper surface of the piezoelectric film 103, a wiring 106a electrically connected to the electrode 104a, and a wiring 106b electrically connected to the electrode 104b.

The piezoelectric film 103 has a region 103a, and a region 103b arranged on the region 103a and having fewer crystal defects than the region 103a. When a crystalline film is formed on another material such as an insulating film, the crystals are likely to be disordered at an initial stage of film formation and are gradually aligned as the film grows. Therefore, in the region 103a of the piezoelectric film 103 in the initial stage of film formation, the crystals are easily disordered and many crystal defects (crystal grain boundaries) are present. The crystal defects (crystal grain boundaries) are boundaries between many crystals (polycrystals) existing in a thin film, and are one of lattice defects in which atoms are arranged discontinuously. The grain boundaries, which are the origin of various functions of materials due to their unique atomic arrangements, often determine the overall performance of materials and devices, even though they exist only in extremely small regions with a width of several nanometers. For example, the crystal defects (crystal grain boundaries) greatly reduce the thermal conductivity and vibration propagation properties of materials.

As described above, it is not preferable to use the region 103a for the piezoelectric element. Therefore, by providing the sidewall insulating films 112a and 112b covering the side surfaces 103A and 103B of the region 103a, respectively, only the region 103b with few crystal defects can be used for the piezoelectric element. By using only the region 103b with few crystal defects of the piezoelectric film 103 for the piezoelectric element, a radio frequency and a high electromechanical coupling coefficient can be obtained.

### OTHER EMBODIMENTS

As described above, although some embodiments have been described, the descriptions and the drawings constituting a portion of the disclosure are illustrative and are not intended to be taken in a restrictive sense. Various alternative embodiments, examples, and operational techniques will become apparent to those skilled in the art from this disclosure. Thus, these embodiments include various other embodiments and the like that are not described herein.

For example, in the piezoelectric element unit 100, the thickness (dimension in the Z direction) of the electrodes 104a and 104b in the vicinity of the piezoelectric film 103 may be thicker than the thickness (dimension in the Z direction) of the piezoelectric film 103, as shown in the piezoelectric element unit 100K. Further, in the piezoelectric element unit 100, the thickness (dimension in the Z direction) of the wirings 106a and 106b may be thicker than the thickness (dimension in the Z direction) of the electrodes 104a and 104b.

What is claimed is:

1. A piezoelectric element unit comprising:
a substrate having a main surface;
a piezoelectric film arranged on the substrate and having a first side surface, a second side surface opposite the first side surface, and a bottom surface that faces the main surface and is connected to the first side surface and the second side surface;
a first electrode arranged on the substrate and in contact with the first side surface of the piezoelectric film; and
a second electrode arranged on the substrate in contact with at least one of the first side surface and the second side surface of the piezoelectric film, and provided to be separated from the first electrode.

2. The piezoelectric element unit of claim 1, wherein the first electrode is in contact with only the first side surface of the piezoelectric film, and
wherein the second electrode is in contact with only the second side surface of the piezoelectric film.

3. The piezoelectric element unit of claim 2, further comprising: a first spacer and a second spacer that are arranged on the substrate with the piezoelectric film interposed between the first spacer and the second spacer, and are separated from the piezoelectric film,
wherein the first electrode is arranged between the piezoelectric film and the first spacer,
wherein the second electrode is arranged between the piezoelectric film and the second spacer, and
wherein the first spacer and the second spacer are made of a same material as a material of the piezoelectric film.

4. The piezoelectric element unit of claim 3, further comprising: a protective film arranged on the piezoelectric film,
wherein a space exists between the protective film and the first electrode in a region between the piezoelectric film and the first spacer, and
wherein a space exists between the protective film and the second electrode in a region between the piezoelectric film and the second spacer.

5. The piezoelectric element unit of claim 1, further comprising a plurality of first electrodes and a plurality of second electrodes,
wherein each of the plurality of first electrodes is in continuous contact with the first side surface of the piezoelectric film through an upper surface of the piezoelectric film to the second side surface of the piezoelectric film,
wherein each of the plurality of second electrodes is in continuous contact with the second side surface of the piezoelectric film through the upper surface of the piezoelectric film to the first side surface of the piezoelectric film, and
wherein the plurality of first electrodes and the plurality of second electrodes are alternately arranged in a direction perpendicular to a normal direction of the main surface and in a direction parallel to the first side surface.

6. The piezoelectric element unit of claim 1, wherein a plurality of first electrodes are in contact with only the first side surface and a plurality of second electrodes are in contact with only the first side surface, and
wherein the plurality of first electrodes and the plurality of second electrodes are alternately arranged in a direction perpendicular to a normal direction of the main surface and in a direction parallel to the first side surface.

7. The piezoelectric element unit of claim 2, further comprising a plurality of first electrodes and a plurality of second electrodes,
wherein, in a direction perpendicular to a film thickness direction of the piezoelectric film and a direction parallel to the first side surface, a distance between the first side surface of the first electrode and the second side surface of the second electrode oriented in a same direction as the first side surface of the first electrode is ½ of a pitch interval of the first electrode.

8. The piezoelectric element unit of claim 3, wherein, when viewed from a normal direction of the main surface, the piezoelectric film has a closed-annular shape, and
wherein the first electrode is arranged along an outer periphery of the piezoelectric film, and the second electrode is arranged along an inner periphery of the piezoelectric film.

9. The piezoelectric element unit of claim 1, wherein the piezoelectric film has a first region and a second region arranged on the first region and having fewer crystal defects than the first region, and
wherein the piezoelectric element unit further comprises a sidewall insulating film configured to cover each of the first side surface and the second side surface in the first region.

10. The piezoelectric element unit of claim 1, wherein the first side surface and the second side surface of the piezoelectric film are exposed as non-polar surfaces, and
wherein the first electrode and the second electrode are in contact with the non-polar surfaces.

11. The piezoelectric element unit of claim 1, wherein the piezoelectric film is oriented along a C-axis with respect to the substrate and extends in a direction perpendicular to a direction of the C-axis.

12. The piezoelectric element unit of claim 1, further comprising: an insulating film arranged on an upper surface of the piezoelectric film.

13. The piezoelectric element unit of claim 1, wherein the first electrode and the second electrode include at least one selected from a group consisting of aluminum, molybdenum, titanium, tungsten, ruthenium, and gold.

14. The piezoelectric element unit of claim 1, wherein the substrate is made of an aluminum nitride with or without at least one selected from a group consisting of scandium, ytterbium, magnesium, niobium, zirconium, titanium, hafnium, and yttrium.

15. The piezoelectric element unit of claim 1, wherein the substrate is made of one type of a single crystal or polycrystal selected from a group consisting of a lithium niobium oxide and a lithium tantalum oxide.

16. A resonator including a plural number of the piezoelectric element unit of claim 1, wherein, in two adjacent piezoelectric element units among the plural number of the piezoelectric element unit, a second electrode of a first piezoelectric element unit is shared with a first electrode of a second piezoelectric element unit to connect the plurality of piezoelectric element units in series with each other.

17. A resonator including a plural number of the piezoelectric element unit of claim 1, wherein the plurality of piezoelectric element units are connected in parallel with each other,
wherein first electrodes of each of the plural number of the piezoelectric element unit are electrically connected to each other, and
wherein second electrodes of each of the plural number of the piezoelectric element unit are electrically connected to each other.
